(19) United States
(12) Patent Application Publication
(10) Pub. No.: US 2008/0305364 A1
(43) Pub. Date: Dec. 11, 2008

(54) Magnetic Recording Media and Production Process Thereof

(75) Inventors: Hiroshi Osawa, Chiba-shi (JP); Gohei Kurokawa, Ichihara-shi (JP)

Correspondence Address: SUGHRUE MION, PLLC, 2100 PENNSYLVANIA AVENUE, N.W., SUITE 800, WASHINGTON, DC, 20037, US

(73) Assignee: Showa Denko K.K., Tokyo (JP)

(21) Appl. No.: 11/660,272

(22) PCT Filed: Aug. 17, 2005
(86) PCT No.: PCT/JP05/15305

§ 371 Date: Aug. 8, 2007

Related U.S. Application Data
(60) Provisional application No. 60/605,499, filed on Aug. 31, 2004.

(30) Foreign Application Priority Data
Aug. 19, 2004 (JP) 2004-239571

(51) Int. Cl. G11B 5/66; H05H 1/24; C23C 14/02; C23C 16/02; G11B 5/33

(52) U.S. Cl. 428/814; 427/535; 427/534; 427/539; 118/723 E; 428/831

(57) ABSTRACT

The present invention is a production method for a magnetic recording media in which at least a magnetic layer, a protective layer, and a lubricant layer are sequentially layered onto a non-magnetic substrate 1, and non-magnetic substrate 1 is surface treated using a gas activated by plasma generated at around atmospheric pressure. As a result of the present invention, it is possible to produce magnetic recording media with good yield that have few errors and superior head floating properties, by effectively removing foreign material and projections present on the surface of the magnetic recording media.

### BACKGROUND OF THE INVENTION

1. Technical Field

The present invention relates to a magnetic recording media, such as a magnetic disk, that is employed in a magnetic recording device, and to a production method therefor. More specifically, the present invention relates to a magnetic recording media in which the floating properties of the head are superior and there are few errors, and to a production method for obtaining this type of magnetic recording media with good yield.

Priority is claimed on Japanese Patent Application No. 2004-239571, filed Aug. 19, 2004, the content of which is incorporated herein by reference, And, priority is claimed on U.S. provisional application No. 60/605,499, filed Aug. 31, 2004, the content of which is incorporated herein by reference

2. Background Art

Magnetic recording media, such as magnetic disks that are employed in magnetic disk devices and other such magnetic recording devices, and optical recording media such as optical disks or magneto-optical disks, have been used as media for recording data. Magnetic disk devices and other such magnetic recording devices have conventionally been used as external recording devices for computers. In recent years, however, the applications for these devices have expanded to include portable music players, DVD recorders and the like. Accompanying the growing importance of these devices, designs have been geared toward increasing capacity to the several hundred gigabyte level. Furthermore, there is a trend to reduce the number of magnetic recording media or magnetic heads per magnetic recording device as one method for reducing the cost of the magnetic recording device. Accordingly, accompanying this trend, a rapid increase in the recording density of each magnetic recording media is anticipated.

A hard disk drive, which is one type of magnetic recording device, typically consists of a magnetic disk, a driver for rotationally driving the magnetic disk, a magnetic head and a driving means therefor, and a magnetic head recording and reproduction means. A representative laminate structure for a magnetic disk is expressed below. Typically, a non-magnetic material is employed as the substrate for the magnetic disk, with these materials roughly divided into aluminum substrates such as Al, or AlMg-based alloys, and non-metallic substrates such as glass, ceramic, carbon, silicon and the like. Aluminum substrates have such merits as being inexpensive and suitable to precision machining, and are widely used as the substrate in 3.5-inch diameter magnetic recording media.

Typically, these substrates are employed after being rendered to a specific thickness, subjecting the surface thereof to mirror polishing, and then forming a surface layer by employing an electroless plating process, etc., to provide a roughly 5 to 20 μm thick film of a non-magnetic metal, such as Ni—P alloy or Ni—Cu—P alloy for example. Texturing is performed as necessary to the surface layer that is formed onto the substrate, with very fine grooves or concavities and convexities being formed with high precision, to form a surface-processed layer to which a specific surface roughness has been provided. As a result of this texturing, the magnetic layer has magnetic anisotropy, adsorption between the magnetic recording media and the magnetic head can be prevented, CSS properties can be improved, and magnetic anisotropy becomes excellent.

On the other hand, non-metallic substrates, typified by glass, have such merits as high mechanical hardness which is suitable for reducing the diameter and thickness of the magnetic disk, and, in recent years, have been used as a substrate for magnetic recording media that are installed in small magnetic disk devices that have a diameter that is 2.5 inches or less in size. Regardless of whether the substrate is aluminum or glass, however, the basic part of the laminate structure formed on top of the substrate is the same. Namely, typically, there is a lower layer, a magnetic layer, a protective layer, a lubricant layer, and the like.

Where there are projections of a certain height, or the presence of foreign matter or debris on the surface of the magnetic disk, errors can occur as a result, leading to crashes of the magnetic head and making it impossible to obtain good head floating properties. For this reason, during the magnetic disk production process, it is typically the case that numerous cleaning processes are provided for washing the surface, removing abnormal projections, etc. Examples of conventional cleaning processes that may be cited include a cleaning process for removing polishing particles or shaving remnants after texturing of the substrate, a cleaning process for removing the electrolytic solution after electrolysis, a cleaning process for removing extremely small projections after carrying out formation of the protective layer, and the like. For the cleaning method, such methods are employed as showering using ultra-pure water, immersion washing, or tape cleaning in which a polishing tape that carries or does not carry polishing particles is brought into contact with the surface of a revolving disk (see Patent Reference Document No. 1).

In cleaning processes such as these, foreign material or projections are removed from the disk surface by being washed away with the cleaning solution, stuck to the tape, or blown by during rotation of the disk.

However, accompanying the change toward higher recording density in magnetic disks, the presence of even microscopic foreign material or projections cannot be tolerated. For example, with higher density recording, errors are readily generated by even microscopic foreign material, and the floating height of the magnetic head is reduced. Even microscopic foreign matter or projections are a cause of deterioration in the floating properties of the head. In other words, the size of the foreign material which must be removed is becoming extremely small. However, the smaller the foreign material, the more readily it adheres to the surface of the disk without smoothly separating from it. Thus, removal of foreign material has become difficult.

Further, the texturing process is a polishing process. Thus, if non-uniform work is performed, deep linear scratches extending in the circumferential direction occur. Reducing scratching is required since these types of scratches are also a source of errors.

Patent Reference Document No. 1: Japanese Unexamined Patent Application, First Publication No.: 2001-312817

### DISCLOSURE OF INVENTION

The present invention was conceived in view of the above-described circumstances and has as one objective the provision of a production method for a magnetic recording media in which magnetic recording media can be produced with good yield that have few errors and superior head floating properties, by effectively removing foreign material and projections present on the surface of the magnetic recording media.

It is a further objective of the present invention to provide a method in which uniform working can be carried out in the texturing process, and data recording media can be produced with good yield that have few errors and superior head floating properties by means of reducing scratching.

In addition, it is an objective of the present invention to provide a magnetic recording media that has few errors and superior head floating properties, in which foreign material and projections present on the surface of the magnetic recording media are effectively removed.

In addition, it is a further objective of the present invention to provide a magnetic recording media in which uniform working is carried out in the texturing process and, moreover, scratching is reduced, the magnetic recording media having few errors and superior head floating properties.

As the result of intensive investigations to resolve the aforementioned problems, the present inventors completed the present invention with the discovery that not only can the wettability of a non-magnetic substrate be improved and uniform texturing be carried out, but also excellent cleaning can be realized by surface treating the non-magnetic substrate using a treatment gas activated by glow discharge plasma generated at around atmospheric pressure.

In other words, the present invention employs the following design in order to achieve the aforementioned objectives.

(1) A production method for a magnetic recording media in which at least a magnetic layer, a protective layer, and a lubricant layer are sequentially layered onto a non-magnetic substrate, characterized in that the non-magnetic substrate is surface treated using a gas activated by plasma generated at around atmospheric pressure.
(2) A production method for a magnetic recording media according to the above (1), characterized in that the plasma is a glow discharge plasma.
(3) A production method for a magnetic recording media according to the above (1) or (2), characterized in that the production method for the magnetic recording media is provided with a texturing process for carrying out texturing to the non-magnetic substrate, and surface treatment of the non-magnetic substrate is carried out using an activated gas prior to the texturing process.
(4) A production method for a magnetic recording media according to any one of the above (1) through (3), characterized in that the production method for the magnetic recording media is provided with a cleaning process for the non-magnetic substrate, and a surface treatment is performed to the non-magnetic substrate using activated gas before and/or after the cleaning process.
(5) A production method for a magnetic recording media according to one of the above (1) through (4), characterized in that the gas is one or more types selected from the group comprising nitrogen, oxygen or argon.
(6) A production method for a magnetic recording media according to any one of the above (1) through (5), characterized in that the plasma generated at around atmospheric pressure impresses an electric field between opposing electrodes.
(7) A production method for a magnetic recording media according to the above (6), characterized in that the opposing electrodes are disposed at an inclination that is 1° to 45° from the perpendicular with respect to the non-magnetic substrate.
(8) A production method for a magnetic recording media according to the above (6) characterized in that the opposing electrodes are perpendicular with respect to the non-magnetic substrate.
(9) A production method for a magnetic recording media according to the above (6), characterized in that the surface treatment is carried out by disposing the non-magnetic substrate between the opposing electrodes.
(10) A production method for a magnetic recording media according to any one of the above (1) through (9), characterized in that a surface treatment using activated gas is simultaneously carried out to both surfaces of the non-magnetic substrate.
(11) A production method for a magnetic recording media according to any one of the above (1) through (10), characterized in that the non-magnetic substrate is one type selected from glass substrate and silicon substrate.
(12) A production method for a magnetic recording media according to one of the above (1) through (10), characterized in that the non-magnetic substrate has a design in which a film consisting of NiP or NiP alloy is formed to the surface of a base consisting of one type selected from Al, Al alloy, glass or silicon.
(13) A magnetic recording media produced by the production method for a magnetic recording media according to one of the above (1) through (12).
(14) A magnetic recording and reproduction device provided with a magnetic recording media and a magnetic head for recording data to and reproducing data from a magnetic recording media, characterized in that the magnetic recording media is a magnetic recording media according to the above (13).
(15) A surface treatment device characterized in having a function in which plasma is generated and an activated gas is formed by impressing an electric field between opposing electrodes at around atmospheric pressure, and the activated gas is radiated onto the surface of the non-magnetic substrate.

The term “texturing” as used here refers to performing high-density linear working in the circumferential direction by mechanical working using solid particles and/or free particles on the surface of the non-magnetic substrate. For example, a polishing tape is pressed into contact with the surface of the substrate, and a polishing slurry that includes polishing grains is supplied between the substrate and the polishing tape. The substrate is then rotated, while at the same time texturing is carried out by feeding the polishing tape. The aforementioned polishing slurry is an aqueous solution that includes polishing grains. For this reason, if the wettability of the surface of the non-magnetic substrate to be worked is poor, the polishing slurry does not spread out uniformly across the surface of the non-magnetic substrate, and, as a result, non-uniform working occurs and numerous scratches are generated. Accordingly, improvement of the wettability of the surface of the non-magnetic substrate leads to fewer scratches and, thus, less errors. A treatment gas activated by plasma generated at around atmospheric pressure is employed, and a surface treatment is carried out to the non-magnetic substrate. As a result, the wettability of the non-magnetic substrate can be improved, so that uniform working in the texturing step can be carried out, and scratches can be reduced.

In order to remove microscopic foreign material in the cleaning process, scrub washing is often carried out using a roll or cap brush. Scrub washing is combined with pure water or an aqueous detergent to remove microscopic foreign material. For this reason, if the wettability of the non-magnetic substrate to be washed is poor, then the pure water or aqueous detergent does not spread across the surface of the non-magnetic substrate. As a result, non-uniform washing results and a uniform cleansing effect cannot be anticipated. Accordingly, improving the wettability of the surface of the non-magnetic substrate provides a uniform cleansing effect, and, thus, reduces errors. In conventional methods, in order to improve the wettability of the surface of the non-magnetic substrate, an alkali or neutral detergent is used. However, these methods are problematic in that, by improving surface wettability by etching the surface, pits were readily generating in the surface of the non-magnetic substrate and these pits resulted in errors. In the present invention, by using a treatment gas activated by plasma generated at around atmospheric pressure, and surface treating the non-magnetic substrate, there is no generation of pits in the surface of the non-magnetic substrate, and the wettability of the non-magnetic substrate can be improved. As a result, errors arising from pits can be prevented.

Scrub washing is effective at removing microscopic foreign material, but is not suitable for removing finely adhered organic dirt. With the development of higher density recording in recent years, such organic residue can no longer be ignored. In order to remove this type of organic residue, it is effective to remove this organic material through decomposition. In the present invention, a treatment gas activated by a plasma generated at around atmospheric pressure is employed to carry out surface treatment of the non-magnetic substrate. Organic residue is decomposed to form H₂O and CO₂, which then evaporate. As a result, an extremely effective method for removing organic residue can be achieved. Accordingly, in the present invention, errors arising from organic residue can be prevented and the floating properties of the head can be improved.

In the production method for a magnetic recording media according to the present invention, foreign material and projections present on the surface of the magnetic recording media can be effectively removed. As a result, it is possible to produce with good yield a magnetic recording media in which there are few errors and the floating properties of the head are superior.

Further, by carrying out a surface treatment to the non-magnetic substrate using the aforementioned activated gas prior to the texturing process, uniform working during texturing can be performed and scratches can be reduced. As a result, it is possible to produce with good yield an data recording media in which there are few errors and the floating properties of the head are superior.

The magnetic recording media according to the present invention is produced by the present invention's production method therefore. As a result, foreign material or projections present on the surface of the magnetic recording media can be effectively removed, so that errors are few and the floating properties of the head are superior.

Further, the magnetic recording media according to the present invention is produced by carrying out a surface treatment to the non-magnetic substrate using the aforementioned activated gas prior to the texturing process. As a result, uniform working during texturing can be performed and scratches can be reduced, so that errors are few and the floating properties of the head are superior.

### BRIEF DESCRIPTION OF THE DRAWINGS

FIG. 1 is a cross-sectional view showing a first embodiment of the magnetic recording media according to the present invention.

FIG. 2 is a schematic structural diagram showing a first embodiment of the plasma generating unit employed in the production of the magnetic recording media according to the present invention.

FIG. 3 is a schematic structural diagram showing another embodiment of the plasma generating unit employed in the production of the magnetic recording media according to the present invention.

FIG. 4 is a schematic structural diagram showing another embodiment of the plasma generating unit employed in the production of the magnetic recording media according to the present invention.

FIG. 5 is a schematic structural diagram showing another embodiment of the plasma generating unit employed in the production of the magnetic recording media according to the present invention.

FIG. 6 is a schematic structural diagram showing another embodiment of the plasma generating unit employed in the production of the magnetic rewarding media according to the present invention.

In the above figures, numeric symbol 1 indicates a non-magnetic substrate, 2 indicates the lower layer, 3 indicates the intermediate layer, 4 indicates the magnetic layer, 5 indicates the protective film layer, 6 indicates the lubricant layer, 21a and 21b indicate the electrode plates, 22 indicates the gas introduction port, 23 indicates the pulse power source, 24 indicates plasma, and 26 indicates the substrate holder, respectively.

### BEST MODE FOR CARRYING OUT THE INVENTION

Preferred embodiments of the present invention will now be explained with reference to the figures.

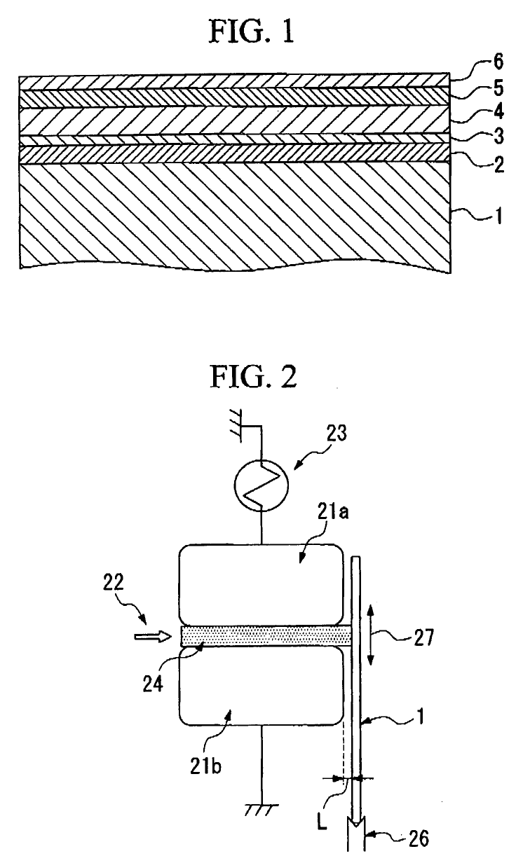

FIG. 1 is a cross-sectional view showing an embodiment of the magnetic recording media according to the present invention.

In the magnetic recording media of the present embodiment, lower layer 2, intermediate layer 3, magnetic layer 4, and protective film layer 5 are sequentially laminated onto non-magnetic substrate 1, with lubricant layer 6 provided as the uppermost layer.

A metallic material such as aluminum or aluminum alloy, or an inorganic material such as glass, ceramic, titanium, carbon, silicon or the like may be used as the material for non-magnetic substrate 1. Non-magnetic substrate 1 is composed of a substrate consisting of an aforementioned metal material or inorganic material, and a surface layer formed by using a plating or sputtering method to deposit a film consisting of one or more materials selected from NiP, NiP alloy or another alloy, onto the surface of the substrate.

Non-magnetic substrate 1 is subjected to a surface treatment using a gas (treatment gas) activated by plasma generated at around atmospheric pressure.

Cr or a Cr alloy consisting of Cr and one or more materials selected from Ti, Mo, Al, Ta, W, Ni, B, Si, Mn and V, can be used as the material for lower layer 2.

When lower layer 2 is formed as a multilayered non-magnetic lower layer, at least one of the structural layers forming the non-magnetic lower layer can be formed of Cr alloy or Cr.

The non-magnetic lower layer can be formed of NiAl alloy, RuAl alloy, or Cr alloy (an alloy consisting of Cr and one or more selected from Ti, Mo, Al, Ta, W, Ni, B, Si and V).

Further, when the non-magnetic lower layer is provided with a multilayered structure, at least one of the structural layers forming the non-magnetic lower layer can be formed of NiAl alloy, RuAl alloy, or Cr alloy.

For the material of intermediate layer 3, it is preferable to employ a non-magnetic material that is a Co alloy having Co as the main ingredient and having a hep structure with the goal of aiding epitaxial growth of the Co alloy. For example, a material including one type selected from a Co—Cr, Co—Cr—Ru, Co—Cr—Ta, or Co—Cr—Zr based alloy is preferred.

For the material of magnetic layer 4, it is preferable to employ a material that is a Co alloy having Co as the main ingredient and having a hep structure. For example, a material including one type selected from a Co—Cr—Ta, Co—Cr—Pt, Co—Cr—Pt—Ta, Co—Cr—Pt—B or Co—Cr—Pt—B—Cu based alloy is preferred.

A carbon based material such as CVD carbon formed by a plasma CVD method, non-crystalline carbon, hydrogen-containing carbon, nitrogen-containing carbon, fluorine-containing carbon or the like, or a ceramic material such as silica or zirconium, can be used as protective film layer 5. Of these, hard, fine CVD carbon is suitably employed not only from the perspective of its durability, but also in view of economy and productivity. When the film in protective film layer 5 is made thin, durability falls. On the other hand, when the film in protective film layer 5 is made thick, loss during recording and reproduction increases. Accordingly, the thickness of protective film layer 5 is set to be on the order of 10 to 150 angstrom (1 to 15 nm), and preferably 20 to 60 angstrom (2 to 6 nm).

The lubricant layer 6 which is the uppermost layer includes a polymer of a perfluoro polyether compound that includes a polymerizable unsaturated group. As an example of the perfluoro polyether compound containing polymerizable unsaturated group, a compound may be cited in which an organic group having polymerizable unsaturated bonds is bonded to at least one end of the main chain perfluoro polyether.

The magnetic recording and reproduction device in this embodiment is provided with a magnetic recording media according to the above-described embodiment having a non-magnetic substrate 1 which was subjected to a surface treatment employing an aforementioned treatment gas, and a magnetic head for recording data in and reproducing data from the aforementioned magnetic recording media.

The surface treatment of a non-magnetic substrate employing gas activated by plasma generated at around atmospheric pressure can be applied to the following three processes:

(1) as a treatment before the texturing process;

(2) as a treatment before the cleaning process; and

(3) as a treatment after the cleaning process,

The purpose of using the aforementioned surface treatment as a (1) treatment before the texturing process and a (2) treatment before the cleaning process is to improve wettability, while the goal of employing the aforementioned surface treatment as a (3) treatment after the cleaning process is to remove organic residue.

The stand-by time from the surface treatment using the aforementioned treatment gas until the texturing process is preferably 48 hours or less. When the stand-by time exceeds 48 hours, wettability deteriorates, so that this is not desirable.

The stand-by time from the surface treatment using the aforementioned treatment gas until the cleaning process is preferably 48 hours or less. When the stand-by time exceeds 48 hours, wettability deteriorates, so that this is not desirable. The stand-by time from the cleaning process until the surface treatment using the aforementioned treatment gas is preferably 24 hours or less. When the stand-by time exceeds 24 hours, the amount of airborne organic matter that re-adheres increases, so that this is not desirable.

Note that it is also acceptable to carry out the surface treatment employing the aforementioned treatment gas during the cleaning process.

An example of the method for producing the magnetic recording media according to the present embodiment will now be explained.

First, a texturing process in which texturing is performed to the surface of a non-magnetic substrate 1 consisting of the aforementioned materials is carried out, after which a cleaning process is performed. It is also acceptable to perform a surface treatment using the aforementioned treatment gas to non-magnetic substrate 1 prior to the texturing process, to perform a surface treatment using the aforementioned treatment gas to non-magnetic substrate 1 prior to and/or after the cleaning process, or to perform a surface treatment using the aforementioned treatment gas to non-magnetic substrate 1 prior to the texturing process and prior to and/or after the cleaning process.

Next, lower layer 2, intermediate layer 3, magnetic layer 4, protective film layer 5, and lubricant layer 6 are sequentially formed on top of non-magnetic substrate 1 to which the aforementioned surface treatment has been performed.

It is preferable that the aforementioned plasma be glow discharge plasma.

It is not absolutely essential that texturing be performed to non-magnetic substrate 1. However, magnetic layer 4 has magnetic anisotropy, adsorption between the magnetic head and the magnetic recording media can be prevented, the CSS properties can be improved and the magnetic anisotropy can be made excellent, so that carrying out texturing is desirable.

In the texturing process referred to here, texturing is carried out to the surface of the non-magnetic substrate in the circumferential direction through mechanical working using a fixed abrasive grain and/or loose abrasive grain. For example, polishing tape is pressed into contact with the surface of substrate 1, and a polishing slurry that includes an abrasive grain for polishing is supplied between the substrate and the polishing tape. Texturing is then carried out by rotating substrate 1 while at the same time feeding the polishing tape.

The speed of rotation of the substrate can be set to be within the range of 200 rpm to 1000 rpm. The amount of polishing slurry supplied can be set to be within the range of 10 ml/min to 100 ml/min. The feeding speed of the polishing tape can be set to be within the range of 1.5 mm/min to 150 mm/min. The particle diameter of the grains that are included in the polishing slurry can be set to be within the range of 0.05 μm to 0.3 μm at D90 (the grain diameter when the cumulative wt % corresponds to 90 wt %). The pressing force of the polishing tape can be set to be within the range of 1 kgf to 15 kgf (9.8N to 147 N).

It is desirable that the average roughness Ra of the surface of non-magnetic substrate 1 to which texturing is formed be in the range of 0.1 nm to 1 nm (1 angstrom to 10 angstrom), and preferably in the range of 0.2 nm to 0.8 nm (2 angstrom to 8 angstrom).

Texturing with added oscillation can also be carried out. The term “oscillation” as used here refers to an operation in which the polishing tape is made to run in the circumferential direction of substrate 1 while, at the same time, the polishing tape is oscillated in the radial direction of substrate 1. The conditions for oscillation are preferably 60 times/minute to 1200 times/minute.

By carrying out surface treatment of non-magnetic substrate 1 using a treatment gas activated by plasma generated at around atmospheric pressure prior to the texturing process, it is possible to improve wettability of non-magnetic substrate 1. Thus, uniform working in the texturing process can be carried out and scratches can be reduced.

Washing (cleaning) of non-magnetic substrate 1 mainly is composed of immersion in an alkali or neutral detergent, scrub washing, shaking dry using pure water or IPA vapor drying. Immersion in the alkali or neutral detergent and the scrub washing may be performed in either order. However, in order to improve the wettability of non-magnetic substrate 1, it is preferable that immersion in the alkali or neutral detergent be performed first. However, there is no need to be overly concerned about this order, as wettability is improved by employing the aforementioned surface treatment according to the present invention.

Further, wettability is improved by carrying out a surface treatment employing the aforementioned treatment gas to non-magnetic substrate 1 prior to the cleaning process. As a result, the alkali or neutral detergent is unnecessary, or the concentration thereof can be greatly reduced, making it possible to limit the occurrence of pitting and prevent the errors caused by such pits. It is preferable to use a cap brush or roll brush for the scrub washing. The speed of rotation of the cap or roll brush is preferably 100 to 500 rpm. When the speed of rotation is less than 100 rpm, the washing effect is weak. On the other hand, at rotation speeds in excess of 500 rpm, the friction between the disk driver (magnetic recording media driver) and the magnetic disk (magnetic recording media) increases, and the generation of dust in the driver becomes greater, so that this is undesirable. Shaking dry using pure water is preferably carried out at a disk rotation speed of 3000 to 6000 rpm. When the rotation speed is less than 3000 rpm, the centrifugal force is insufficient and sufficient water removal is impossible. On the other hand, the drying effect does not change even at speeds in excess of 6000 rpm, so that there is no need to increase the load on the rotational driver beyond what is required.

By performing a surface treatment to non-magnetic substrate 1 using the aforementioned treatment gas after the cleaning process, organic residue is decomposed into H₂O and CO₂, and evaporates. As a result, there is improved efficacy in removing the organic residue, the errors caused by such organic residue can be prevented, and the floating properties of the head can be improved.

A plasma generating unit capable of generating plasma stably at around atmospheric pressure may be used as the surface treatment device employed in the surface treatment in the present embodiment. For example, the atmospheric pressure plasma surface reforming unit manufactured by Sekisui Chemical Co., Ltd., an Aiplasma cleaning head manufactured by Matsushita Electric Works, Ltd., or the like may be employed.

The term “pressure at around atmospheric pressure” indicates a pressure in the range of 1.3×10⁴ to 13×10⁴ Pa. In particular, employing the unit in a pressure range of 9.9×10⁴ to 10.3×10⁴ Pa is desirable as pressure adjustment is easy and the device structure is simple.

The plasma generating unit according to this embodiment will now be explained using FIG. 2.

The plasma generating unit in FIG. 2 is composed primarily of a pair of opposing electrode plates (opposing electrodes) 21a,21b, a gas introduction port 22 for supplying gas between electrode plates 21a,21b, a pulse power source 23 for impressing an electric field between the opposing electrodes, and a substrate holder 26 for holding non-magnetic substrate 1.

This plasma generating unit has the function of generating plasma by impressing an electric field between the pair of electrode plates 21a,21b, to form an activated gas, and then radiating this activated gas onto the surface of non-magnetic substrate 1.

Iron, copper, and aluminum, as well as alloys thereof, may be used as the material for the respective electrode plates. The distance between the opposing electrodes is preferably 0.1 to 50 mm, and more preferably 0.1 to 5 mm when taking into consideration the plasma discharge stability.

A pulse wave, high-frequency wave, microwave or the like may be employed as the electric field applied between electrode plates 21a,21b. However, it is more preferable to used a pulse wave that enables adjustment of the length of time that the electric field is impressed. The frequency of the pulse wave is in the range of 1 to 500 kHz, and, in particular, is preferably set to 1 to 50 kHz when taking into consideration plasma discharge stability. The length of time that the electric field is impressed, i.e., the continuous duration of the pulse wave, is preferably 0.5 to 200 μsee. When the duration is 0.5 μsee or less, plasma discharge is not established, while when the duration exceeds 200 μsee, arcing readily occurs, so that this is not desirable.

It is preferable that nitrogen, oxygen, argon or a mixture thereof is employed as the gas supplied between electrode plates 21a,21b. Since a pressure at around atmospheric pressure is employed, the amount of gas consumed is large, so that it is more preferable to use inexpensive nitrogen, oxygen or a mixed gas of nitrogen and oxygen.

In FIG. 2, a pair of electrode plates 21a,21b is disposed perpendicular with respect to non-magnetic substrate 1 prior to the surface treatment. Plasma is generated between the electrodes. However, since the plasma spreads, a plasma state is generated in an area that projects out from the electrodes. The distance L from the end of the opposing electrode plates to non-magnetic substrate 1 is preferably 0.1 to 5 mm. When distance L is less than 0.1 mm, there is a concern that non-magnetic substrate 1 will hit the electrode plate, so that this is not desirable. When distance L exceeds 5 mm, the plasma spreads too much, so that efficacy is greatly diminished and the surface treatment effect cannot be obtained. The gas supplied between the pair of electrode plates 21a,21b at around atmospheric pressure is activated by the plasma generated between the electrodes, to form the treatment gas. This treatment gas has extremely high molecular density. As a result, collisions between the molecules occur frequently, so that activity falls. By employing this treatment gas in the surface treatment of the non-magnetic substrate, not only can the wettability of the non-magnetic substrate be improved and uniform texturing can be performed, but excellent cleaning can be realized.

In order to use both surfaces of the magnetic recording media (magnetic disk), it is preferable to employ a carrying method which does not contact the surfaces of the substrate. Accordingly, it is preferable to carry the magnetic recording media by holding the inner or outer edge of non-magnetic substrate 1. It is preferable to set the carrying speed to 10 to 2000 mm/min. A carrying speed of 100 to 1000 mm/min is even more preferable when taking into consideration the efficacy of the surface treatment and achieving a higher through-put. With regard to the carrying method, it is possible for either, substrate 1 or the plasma generating unit to move. In the case of a carrying method in which substrate 1 moves, a mechanism that is capable of being vertically raised and lowered is used as substrate holder 26, for example. By employing this mechanism, substrate 1 can be moved and the surface of the non-magnetic substrate can be sequentially treated with the treatment gas.

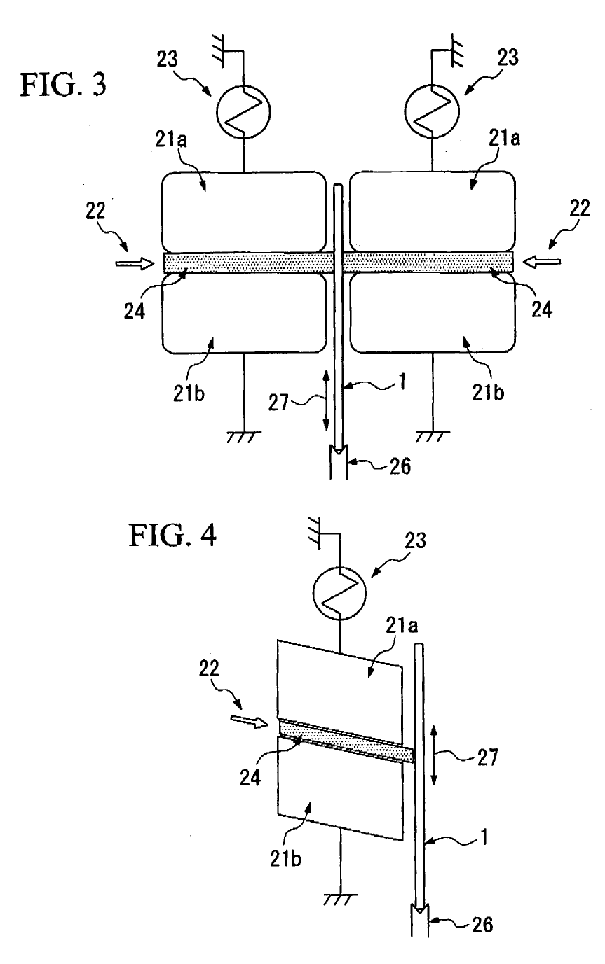

In order to use both surfaces of the magnetic recording media, it is preferable to dispose a plasma generating unit identical to that described above to both sides of substrate 1 as shown in FIG. 3, and perform a surface treatment to both sides of substrate 1 using gas activated by plasma generated at around atmospheric pressure.

When carrying the magnetic recording media by holding the inner or outer edge of substrate 1, the inner or outer edge of substrate 1 becomes hidden in the shadow of holder 26, and there is a concern that the efficacy of the surface treatment at this hidden area will decline.

In order to prevent this, it is preferable to dispose the pair of opposing electrode plates 21a,21b at an incline of 1° to 45° from the perpendicular with respect to non-magnetic substrate 1 as shown in FIG. 4. Note that FIG. 4 shows an example of the device in the case where carrying is accomplished by holding the outer edge of non-magnetic substrate 1.

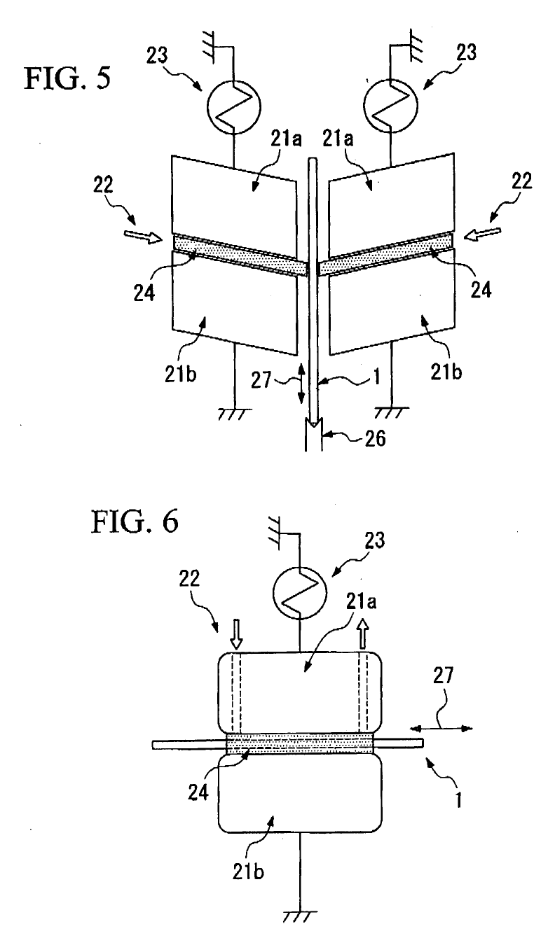

When the surface treatment is carried out after disposing the pair of opposing electrode plates 21a,21b at an incline of 1° to 45° from the perpendicular with respect to non-magnetic substrate 1, the plasma is diagonally radiated at substrate 1 and, as a result, the treatment gas activated by the plasma comes into contact with the portion that is in the shadow of holder 26. In this case as well, it is preferable to dispose a plasma generating unit to both sides of non-magnetic substrate 1 as shown in FIG. 5.

As shown in FIG. 6, by passing non-magnetic substrate 1 between the opposing pair of electrode plates 21a,21b, it is possible to carry out the surface treatment to both sides of substrate 1. In this case, the plasma density is high, so that an even more intense surface treatment can be performed.

Note that in FIGS. 2 to 6, numeric symbol 27 indicates the direction of progression (i.e., the transfer direction) of non-magnetic substrate 1.

The plasma generating unit (surface treatment device) of the above-described design may be incorporated into the texturing device and/or the cleaning device, may be provided separately from the texturing device, or may be provided separately from the cleaning device.

### EXAMPLES

### Comparative Example 1

An aluminum alloy substrate (diameter: 95 mm, inner radius: 25 mm, plate thickness: 1.27 mm) having a NiP plated film was employed as the substrate.

A texturing process was first carried out to the aforementioned substrate. The conditions for the texturing work were as follows. Diamond grains in which the D90 was 0.15 μm were employed for the grains included in the slurry. The slurry was added dropwise for 2 seconds at a rate of 50 ml/min before the texturing work began. A polyester woven cloth was employed for the polishing tape. The polishing tape was fed at a speed of 75 mm/minute. The speed of rotation of the substrate was 600 rpm, and the oscillation of the substrate was 120 times/minute. The pressing force of the tape was 2.0 kgf (19.6 N). The working time was 10 seconds. The surface of the substrate was measured with AFM manufactured by Digital Instrument Co. The average roughness Ra was 4 angstroms (0.4 nm).

Next, a cleaning process was performed to the aforementioned substrate. In the cleaning process, the substrate was rinsed with a pure water shower, followed by immersion for 10 minutes in a soaking layer in which 5 wt % of a nonionic surfactant (neutral detergent) was dissolved in pure water. The substrate was then rinsed in a pure water shower, after which scrub washing was performed.

Washing was performed by pressing a cap brush consisting of a polyurethane-derived compound material rotating at 300 rpm against the substrate. The substrate was then rinsed in a pure water shower, and dried by shaking in pure water at 4000 rpm.

Next, the substrate was placed in a DC magnetron sputtering device (C3010, manufactured by Anelva Corporation). The chamber was evacuated to a vacuum pressure of 2×10⁻⁷ Torr (2.7×10⁻⁵ Pa), after which the substrate was heated to 250° C. Following heating, a target consisting of Cr was employed and laminated to a thickness of 5 nm onto the substrate for the non-magnetic lower layer. A target consisting of a Cr—Mo alloy (Cr: 80 at %, Mo; 20 at %) was then employed and laminated to a thickness of 5 nm for the non-magnetic lower layer. Next, a target consisting of Co—Cr alloy (Co: 65 at %, Cr: 35 at %) was employed and laminated to a thickness of 2 nm onto this non-magnetic lower layer, for the non-magnetic intermediate layer. Next, for the magnetic layer, a target consisting of Co—Cr—Pt—B alloy (Co: 60 at %, Cr: 22 at %, Pt: 12 at %, B: 6 at %) was employed to form a Co—Cr—Pt—B alloy layer as a 20 nm thick film onto this non-magnetic intermediate layer. Next, a plasma CVD device was employed to form a protective film consisting of CVD carbon having a thickness of 5 nm. The Ar pressure at the time of formation of the film was 3 mTorr (0.4 Pa).

Next, a lubricant consisting of perfluoro poly ether was adjusted to 0.05 wt % and coated to the surface of the protective film at a lifting speed of 3 mm/sec. Note that the solvent employed at this time was AK225, a fluorine-based solvent manufactured by Asahi Glass Co. Ltd.

In this way, a magnetic recording media according to Comparative Example 1 was obtained.

### Examples 1 to 17

Magnetic recording media (Examples 1 to 17) were obtained in the same manner as in Comparative Example 1, with the exception that the surface treatment using treatment gas according to the present invention was performed as a treatment prior to texturing. The conditions for the surface treatment are shown in Table 1.

### Examples 18 to 22

Magnetic recording media (Examples 18 to 22) were obtained in the same manner as in Comparative Example 1, with the exception that the aforementioned surface treatment using treatment gas was performed after the cleaning process. The conditions for the surface treatment are shown in Table 2.

### Examples 23 to 27

Magnetic recording media (Examples 23 to 27) were obtained in the same manner as in Comparative Example 1, with the exception that the aforementioned surface treatment using treatment gas was performed as a treatment after texturing and prior to cleaning, and that the aforementioned surface treatment using treatment gas was further performed following the cleaning process. The conditions for the surface treatment are shown in Table 3.

### Comparative Example 2

Amorphous glass GD-7 manufactured by Asahi Glass Co. was employed as the substrate. The glass substrate had an outer diameter of 65 mm, an inner diameter of 20 mm and a plate thickness of 0.635 mm.

A cleaning process was first performed to the aforementioned substrate. In the cleaning process, the substrate was rinsed with a pure water shower, followed by immersion for 10 minutes in an immersion vat in which 5 wt % of an alkali detergent had been dissolved in pure water. The substrate was then rinsed in a pure water shower, after which scrub washing was performed. Washing was performed by pressing a cap brush consisting of a polyurethane-derived compound material rotating at 300 rpm against the substrate.

The substrate was then rinsed in a pure water shower, and shaken dry in pure water at 4000 rpm.

Next, the substrate was placed in a DC magnetron sputtering device (C3010, manufactured by Anelva Corporation), and the chamber was evacuated to a vacuum pressure of 2×10⁻⁷ Torr (2.7×10⁻⁵ Pa). For the orientation modified film, a target consisting of Co—W alloy (Co: 50 at %, W: 50 at %) was laminated to a thickness of 5 nm at room temperature.

Next, this substrate was heated to 250° C. Following heating, oxygen exposure was performed for 5 seconds at 0.05 Pa. Next, a target consisting of Cr—Ti—B alloy (Cr: 83 at %, Ti: 15 at %, B: 2 at %) was laminated to a thickness of 8 nm onto the substrate as a non-magnetic lower layer. Next, a target consisting of Co—Cr alloy (Co: 65 at %, Cr: 35 at %) was employed and laminated to a thickness of 2 nm onto this non-magnetic lower layer as a non-magnetic intermediate layer. Next, as a magnetic layer, a target consisting of Co—Cr—Pt—B alloy (Co: 60 at %, Cr; 22 at %, Pt: 12 at %, B: 6 at %) was employed to form a CoCrPtB alloy layer as a 20 nm thick film onto this non-magnetic intermediate layer. Next, a protective film (carbon) was laminated to a thickness of 5 nm. The Ar pressure at the time of formation of the film was 3 mTorr (0.4 Pa). Next, a lubricant consisting of perfluoro polyether was adjusted to 0.05 wt % and coated to the surface of the protective film at a lifting speed of 3 mm/sec using a dipping method. Note that the solvent employed at this time was AK225, a fluorine-based solvent manufactured by Asahi Glass Co. Ltd.

In this way, a magnetic recording media according to Comparative Example 2 was obtained.

### Examples 28 to 32

Magnetic recording media (Examples 28 to 32) were obtained in the same manner as in Comparative Example 2, with the exception that the aforementioned surface treatment using treatment gas was performed before the cleaning process. The conditions for the surface treatment are shown in Table 4.

### Examples 33 to 37

Magnetic recording media (Examples 33 to 37) were obtained in the same manner as in Comparative Example 2, with the exception that the aforementioned surface treatment using treatment gas was performed as a treatment prior to cleaning, and pure water was employed in place of the alkali detergent used in the cleaning process. The conditions for the surface treatment are shown in Table 5.

In each of the above embodiments, an atmospheric pressure plasma surface reforming unit manufactured by Sekisui Chemical Co., Ltd. was used for the plasma generating unit (surface treatment device), and a surface treatment using treatment gas was performed to the non-magnetic substrate in the arrangement shown in FIG. 2. The carrying speed (substrate transfer speed), N₂ flow volume, O₂ flow volume, and the distance from one end (the end near the non-magnetic substrate) of the opposing electrodes to the non-magnetic substrate was varied.

Glide tests were then carried out on the magnetic recording media in the Examples and Comparative Examples above using a glide tester with the glide height set to 0.4 microinch as a test condition. Error detection was then carried out for the magnetic recording media that passed the glide test.

The error test was carried out using an R/W tester. A head having a cap length of 0.3 μm was employed for the detection head. The recording frequency was 250 kFCI. The error was set to a location where the output was in excess of ±30% with respect to a standard value. The error number was counted by assigning one bit length (0.1 μm) as one unit. A radius in the range of 20 mm to 45 mm was employed for Examples 1 to 27 and Comparative Example 1, while a radius in the range of 15 mm to 30 mm was employed for Examples 28 to 37 and Comparative Example 2. Error detection was carried out with each of the preceding at 1 μm, and the error number was calculated.

Further, the contact angle after surface treatment was calculated for each of the examples using a water contact angle meter. The contact angle was also measured using a water contact angle meter for the comparative examples.

TABLE 1

| | | | | Distance from the | | | |
|---|---|---|---|---|---|---|---|
| | | | | end of opposing | Contact angle | | |
| | Carrying Speed | N₂ flow rate | O₂ flow rate | electrodes to | Before plasma | After plasma | |
| | (mm/min) | (l/min) | (l/min) | the substrate (mm) | treatment (T°) | treatment (T°) | Error number |
| Example 1 | 100 | 40 | 0 | 2 | 45.3 | 4.5 | 6 |
| Example 2 | 300 | 40 | 0 | 2 | 44.8 | 4.5 | 5 |
| Example 3 | 600 | 40 | 0 | 2 | 44.5 | 4.9 | 8 |
| Example 4 | 1000 | 40 | 0 | 2 | 45.6 | 4.2 | 9 |
| Example 5 | 2000 | 40 | 0 | 2 | 45.1 | 12.3 | 18 |
| Example 6 | 600 | 40 | 0 | 1 | 45.2 | 4.9 | 5 |
| Example 7 | 600 | 40 | 0 | 3 | 45.9 | 4.8 | 4 |
| Example 8 | 600 | 40 | 0 | 5 | 43.1 | 12.1 | 22 |
| Example 9 | 600 | 40 | 0 | 10 | 46.1 | 45.9 | 115 |
| Example 10 | 600 | 1 | 0 | 2 | 45.2 | 22.9 | 21 |
| Example 11 | 600 | 10 | 0 | 2 | 44.3 | 4.1 | 5 |
| Example 12 | 600 | 20 | 0 | 2 | 43.9 | 4.5 | 4 |
| Example 13 | 600 | 100 | 0 | 2 | 43.1 | 4.9 | 7 |
| Example 14 | 600 | 200 | 0 | 2 | 44.9 | 4.5 | 4 |
| Example 15 | 600 | 40 | 5 | 2 | 44.8 | 4.2 | 8 |
| Example 16 | 600 | 40 | 20 | 2 | 44.3 | 4.5 | 4 |
| Example 17 | 600 | 40 | 40 | 2 | 44.7 | 4.9 | 5 |

| | | | | |
|---|---|---|---|---|
| Comp. Ex. 1 | No plasma treatment | 45.3 | — | 120 |

TABLE 2

| | | | | Distance from the | | | |
|---|---|---|---|---|---|---|---|
| | | | | end of opposing | Contact angle | | |
| | Carrying Speed | N₂ flow rate | O₂ flow rate | electrodes to | Before plasma | After plasma | |
| | (mm/min) | (l/min) | (l/min) | the substrate (mm) | treatment (T°) | treatment (T°) | Error number |
| Example 18 | 100 | 40 | 0 | 2 | 8.5 | 4.2 | 5 |
| Example 19 | 300 | 40 | 0 | 2 | 8.7 | 4.1 | 7 |
| Example 20 | 600 | 40 | 0 | 2 | 8.9 | 4.9 | 8 |
| Example 21 | 600 | 40 | 0 | 1 | 8.5 | 3.5 | 5 |
| Example 22 | 600 | 40 | 0 | 5 | 8.1 | 19.7 | 25 |

| | | | | |
|---|---|---|---|---|
| Comp. Ex. 1 | No plasma treatment | 8.9 | — | 120 |

TABLE 3

| | Plasma treatment prior to texturing | | | | Plasma treatment after cleaning | | | | |
|---|---|---|---|---|---|---|---|---|---|
| | | | | Distance from the | | | | Distance from the | |
| | Carrying | N₂ flow | O₂ flow | end of opposing | Carrying | N₂ flow | O₂ flow | end of opposing | |
| | Speed | rate | rate | electrodes to | Speed | rate | rate | electrodes to the | Error |
| | (mm/min) | (l/min) | (l/min) | the substrate (mm) | (mm/min) | (l/min) | (l/min) | substrate(mm) | number |
| Example 23 | 100 | 40 | 0 | 2 | 100 | 40 | 0 | 2 | 2 |
| Example 24 | 300 | 40 | 0 | 2 | 300 | 40 | 0 | 2 | 3 |
| Example 25 | 600 | 40 | 0 | 2 | 600 | 40 | 0 | 2 | 3 |
| Example 26 | 600 | 40 | 0 | 1 | 600 | 40 | 0 | 1 | 2 |
| Example 27 | 600 | 40 | 0 | 5 | 600 | 40 | 0 | 5 | 16 |

| | | |
|---|---|---|
| Comp. Ex. 1 | No plasma treatment | 120 |

TABLE 4

| | | | | Distance from the | | | |
|---|---|---|---|---|---|---|---|
| | | | | end of opposing | Contact angle | | |
| | Carrying Speed | N₂ flow rate | O₂ flow rate | electrodes to | Before plasma | After plasma | |
| | (mm/min) | (l/min) | (l/min) | the substrate (mm) | treatment (T°) | treatment (T°) | Error number |
| Example 28 | 100 | 40 | 0 | 2 | 17.2 | 4.1 | 4 |
| Example 29 | 300 | 40 | 0 | 2 | 17.1 | 4.3 | 6 |
| Example 30 | 600 | 40 | 0 | 2 | 18.2 | 4.7 | 5 |
| Example 31 | 600 | 40 | 0 | 1 | 17.3 | 4.5 | 4 |
| Example 32 | 600 | 40 | 0 | 5 | 16.9 | 10.5 | 19 |

| | | | | |
|---|---|---|---|---|
| Comp. Ex. 2 | No plasma treatment | 17.3 | — | 89 |

TABLE 5

| | | | | Distance from the | | | |
|---|---|---|---|---|---|---|---|
| | | | | end of opposing | Contact angle | | |
| | Carrying Speed | N₂ flow rate | O₂ flow rate | electrodes to | Before plasma | After plasma | |
| | (mm/min) | (l/min) | (l/min) | the substrate (mm) | treatment (T°) | treatment (T°) | Error number |
| Example 33 | 100 | 40 | 0 | 2 | 17.8 | 4.5 | 2 |
| Example 34 | 300 | 40 | 0 | 2 | 17.3 | 4.1 | 4 |
| Example 35 | 600 | 40 | 0 | 2 | 16.4 | 3.9 | 3 |
| Example 36 | 600 | 40 | 0 | 1 | 18.3 | 3.5 | 2 |
| Example 37 | 600 | 40 | 0 | 5 | 17.5 | 11.2 | 11 |

| | | | | |
|---|---|---|---|---|
| Comp. Ex. 2 | No plasma treatment | 17.5 | — | 89 |

As may be understood from the results shown in Table 1, by carrying out a surface treatment using the treatment gas according to the present invention, it is possible to greatly improve the contact angle. As a result, texturing becomes uniform and the error number is greatly reduced.

Further, as may be understood from the results shown in Table 2, the surface treatment after the cleaning process also has a large effect on reducing the error number.

Further, as may be understood from the results shown in Table 3, carrying out a surface treatment prior to the texturing process and a surface treatment after the cleaning process provides an even more pronounced affect.

Further, as may be understood from the results shown in Table 4, the surface treatment prior to the cleaning process also has a large effect on reducing the error number.

Further, it may be understood from results shown in Table 5 that the error number fells further still as a result of changing the immersion from an alkali detergent to pure water.

From the above results, it may be understood that treating a non-magnetic substrate with plasma at around atmospheric pressure not only improves wettability of the non-magnetic substrate and enables a uniform texturing process to be carried out, but also makes it possible to realize an excellent cleaning. Moreover, the efficacy in reducing organic residue after cleaning is also clear.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

1. A production method for a magnetic recording media in which at least a magnetic layer, a protective layer, and a lubricant layer are sequentially layered onto a non-magnetic substrate, characterized in that a non-magnetic substrate is surface treated using a gas activated by plasma generated at around atmospheric pressure.

2. A production method for a magnetic recording media according to claim 1, characterized in that said plasma is a glow discharge plasma.

3. A production method for a magnetic recording media according to the above claim 1, characterized in that said magnetic recording media production method is provided with a texturing process for carrying out texturing to said non-magnetic substrate, and surface treatment of said non-magnetic substrate is carried out using an activated gas prior to said texturing process.

4. A production method for a magnetic recording media according to the above claim 1, characterized in that said magnetic recording media production method is provided with a cleaning process for said non-magnetic substrate, and a surface treatment is performed to said non-magnetic substrate using activated gas before and/or after said cleaning process.

5. A production method for a magnetic recording media according to the above claim 1, characterized in that the gas is one or more types selected from the group comprising nitrogen, oxygen or argon.

6. A production method for a magnetic recording media according to the above claim 1, characterized in that said plasma generated at around atmospheric pressure impresses an electric field between opposing electrodes.

7. A production method for a magnetic recording media according to claim 6, characterized in that said opposing electrodes are disposed at an inclination that is 1° to 45° from the perpendicular with respect to said non-magnetic substrate.

8. A production method for a magnetic recording media according to claim 6 characterized in that said opposing electrodes are perpendicular with respect to said nonmagnetic substrate.

9. A production method for a magnetic recording media according to claim 6, characterized in that said surface treatment is carried out by disposing said non-magnetic substrate between said opposing electrodes.

10. A production method for a magnetic recording media according to the above claim 1, characterized in that a surface treatment using said activated gas is simultaneously carried out to both surfaces of said non-magnetic substrate.

11. A production method for a magnetic recording media according to the above claim 1, characterized in that said non-magnetic substrate is one type selected from glass substrate and silicon substrate.

12. A production method for a magnetic recording media according to the above claim 1, characterized in that said non-magnetic substrate has a design in which a film consisting of NiP or NiP alloy is formed to the surface of a base consisting of one type selected from Al, Al alloy, glass or silicon.

13. A magnetic recording media produced by the production method for a magnetic recording media according to claim 1.

14. A magnetic recording and reproduction device provided with a magnetic recording media and a magnetic head for recording data to and reproducing data from said magnetic recording media, characterized in that said magnetic recording media is the magnetic recording media according to claim 13.

15. A surface treatment device characterized in having a function in which plasma is generated and an activated gas is formed by impressing an electric field between opposing electrodes at around atmospheric pressure, and the activated gas is radiated onto the surface of the non-magnetic substrate.
